(19) United States
(12) Patent Application Publication
(10) Pub. No.: US 2021/0126141 A1
(43) Pub. Date: Apr. 29, 2021

(54) CONDUCTIVE PASTE FOR N-TYPE SOLAR CELL, METHOD FOR MANUFACTURING N-TYPE SOLAR CELL AND N-TYPE SOLAR CELL

(71) Applicant: DUPONT ELECTRONICS, INC., Wilmington, DE (US)

(72) Inventor: CHE-HSIU SHIH, TAOYUAN CITY (TW)

(21) Appl. No.: 17/064,358

(22) Filed: Oct. 6, 2020

Related U.S. Application Data
(60) Provisional application No. 62/925,987, filed on Oct. 25, 2019.

(51) Int. Cl. H01L 31/0224; H01B 1/22; C03C 4/14; C03C 8/18; C03C 8/10

(52) U.S. Cl. CPC H01L 31/022425; H01B 1/22; H01L 31/02168; C03C 8/18; C03C 8/10; C03C 4/14

(57) ABSTRACT

A conductive paste for N-type solar cells, comprising (a) 70 to 99.75 wt % of a silver power; (b) 0.1 to 3.0 wt % of an aluminum powder, wherein D50 of the aluminum powder is not larger than 3 μm; (c) 5 to 10 wt % of a glass frit; and (d) 3 to 30 wt % of an organic medium; wherein % is based on the total weight of the paste composition.

### FIELD OF THE INVENTION

This invention relates to solar cell electrodes and, in particular, relates to solar cell electrodes formed on N-type substrate.

### TECHNICAL BACKGROUND OF THE INVENTION

In the solar cell industry, fierce competition for better power generation efficiency has been increasing, in which even 0.1% better efficiency performance is sought for as the efficiency becomes close to the theoretical limit.

There has recently been increasing interest in N-type solar cells, especially introducing the Tunnel Oxide Passivated Contacts (TOPCon) technology which boosts overall cell efficiency significantly, wherein the front face is p-type doped.

US20150357489 discloses a paste for N-type solar cells, comprising Ag particles; Al particles in a range from about 0.01 to about 5 wt. %, based on the total weight of the paste; a vehicle; a glass frit in a range from about 0.1 to about 5 wt. %, based on the total weight of the paste, wherein the glass frit comprises a first glass frit with a glass transition temperature Tgl and a further glass frit with a glass transition temperature Tgf, wherein Tgf differs from Tgl by at least about 10° C.; and an additive.

US20150333197 discloses a conductive paste for N-type solar cells, comprising (i) 60 wt 0 to 95 of a conductive powder, (ii) 0.4 wt % to 3.0 wt % of an aluminum powder, (iii) 0.1 wt % to 10 wt % of a glass frit, (iv) 3 wt % to 30 wt % of an organic medium, (v) 0.4 wt % to 1.7 wt % of an amide compound, wherein the wt % are based on the total weight of the conductive paste.

### SUMMARY OF THE INVENTION

In one aspect, the present invention is a conductive paste for N-type solar cells, comprising (a) 70 to 99.75 wt % of a silver power; (b) 0.1 to 3.0 wt % of an aluminum powder, wherein D50 of the aluminum powder is not larger than 3 μm; (c) 5 to 10 wt % of a glass frit; and (d) 3 to 30 wt % of an organic medium; wherein wt % is based on the total weight of the paste composition.

In another aspect, the present invention is a method for manufacturing N-type solar cells, comprising the steps of: preparing an N-type solar cell substrate, wherein the N-type solar cell substrate comprises an n-doped semiconductor substrate, a p-type emitter formed on one side of the semiconductor substrate, and a passivation layer formed on the p-type emitter; applying a conductive paste on the semiconductor substrate, wherein the conductive paste comprises (a) 70 to 99.75 wt % of a silver power; (b) 0.1 to 3.0 wt % of an aluminum powder, wherein 050 of the aluminum powder is not larger 3pm; (c) 5 to 10 wt % of a glass frit; and (d) 3 to 30 wt % of an organic vehicle; wherein wt % is based on the total weight of the paste composition; and firing the applied conductive paste to form a solar cell electrode in electric contact with the p-type emitter.

In another aspect, the present invention is an N-type solar cell comprising electrode formed from the conductive paste above.

### BRIEF DESCRIPTION OF THE DRAWINGS

FIG. 1 shows a manufacturing process of a p-type electrode of an N-type solar cell,

### DETAILED DESCRIPTION OF THE INVENTION

The following shows an embodiment of the manufacturing process of solar cell electrodes. However, the invention is not limited to the following embodiment. It should be understood that although the present invention has been specifically disclosed by preferred embodiments and optional features, modification, improvement and variation of the inventions herein disclosed may be resorted to by those skilled in the art, and that such modifications, improvements and variations are considered to be within the scope of this invention.

### Method of Manufacturing a P-Type Electrode

An N-type solar cell substrate comprising an n-doped semiconductor substrate (n-base layer) 10 and a p-type emitter 20 is prepared.

The n-base layer can be defined as a semiconductor layer containing an impurity called donor dopant where the donor dopant introduces extra valence electrons in the semiconductor element. In the n-base layer, free electrons are generated from the donor dopant in the conduction band.

By adding an impurity to an intrinsic semiconductor as above, electrical conductivity can be varied not only by the number of impurity atoms but also, by the type of impurity atom and the changes can be a thousand-fold and a million-fold.

The n-base layer 10 can be formed by doping a silicon wafer with a donor impurity such as phosphorus.

The p-type emitter 20 can be defined as a semiconductor layer containing an impurity called acceptor dopant where the acceptor dopant introduces deficiency of valence electrons in the semiconductor element. In the p-type emitter, the acceptor dopant takes in free electrons from semiconductor element and consequently positively charged holes are generated in the valence band.

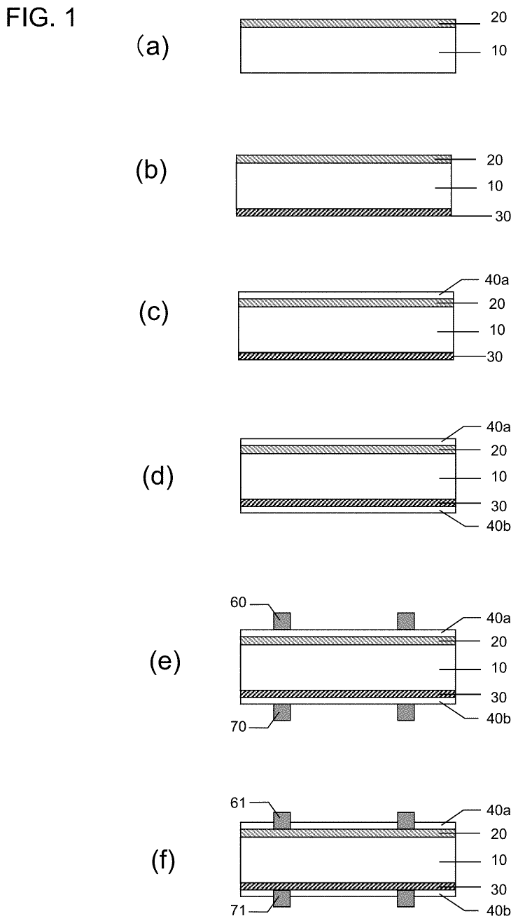

The p-type emitter 20 can be formed, for example, by hermal diffusion of an acceptor dopant into the N-type semiconductor substrate (FIG. 1(a)). The acceptor dopant source can be a boron compound such as boron tribromide (BBr₃), The thickness of the p-type emitter can be, for example, 0.1 to 10% of the N-type semiconductor substrate thickness.

Then an n⁺-layer 30 can be formed at the other side of the p-type emitter 20 (FIG. 1(b)), although it is not essential. The n⁺-layer 30 contains the donor impurity with higher concentration than that in the n-base layer 10. For example, the n⁺-layer 30 can be formed by thermal diffusion of phosphorus in the case of silicon semiconductor using phosphorus oxychloride (POCl₃) as a dopant source. By forming the n⁺-layer 30, the recombination of electrons and holes at the border of the n-base layer 10 and the ntlayer 30 can be reduced.

A first passivation layer 40a can be formed on the p-type emitter 20 (FIG. 1(c)). The first passivation layer 40a can be 10 to 2000Å thick, Silicon nitride (SiNₓ), amorphous silicon (a-Si), silicon carbide (SiCₓ), Titanium oxide (TiOₓ), Aluminum oxide (AlOₓ), Silicon oxide (SiOₓ), Indium Tin Oxide (ITO), or a mixture thereof can be used as a material of the passivation layer 40. The first passivation layer 40a can be formed by, for example, plasma enhanced chemical vapor deposition (PECVD) of these materials.

When the n⁺-layer 30 is formed, the N-type semiconductor substrate comprises the n⁺-layer between the n-base layer 10 and a passivation layer 40 which is formed in the next step.

A second passivation layer 40b is formed on the n⁺-layer 30 (FIG. 1(d)). The material and forming method of the second passivation layer 40b can be the same as those for the first passivation layer 40a. However, the second passivation layer 40b on the n⁺-layer 30 can be different from the first passivation layer 40a in terms of its forming material, its thickness, or its forming method.

When the N-type solar cell is illuminated by sunlight in the operation of the solar cell, the passivation layer(s) 40a and/or 40b reduces the carrier recombination at the surface, and reduces optical reflection losses so that it is also called an anti-reflection coating (“ARC”). In one embodiment, both sides of n-base layer 10 and p-type emitter 20 can be light receiving sides in the operation (bifacial cell). In another embodiment, the first passivation layer 40a is formed on the sun-light receiving side (front side) and the second passivation layer 40b is formed on the rear side. In another embodiment, the second passivation layer 40b is formed on the sun-light receiving side and the first passivation layer 40a is formed on the rear side.

A conductive paste 60 for forming p-type electrodes is applied onto the first passivation layer 40a formed on the p-type emitter 20 (FIG. 1(e)) by a patterning method such as screen printing, stencil printing or dispensing in an embodiment. The applied conductive paste 60 is then dried for 10 seconds to 10 minutes at 50-200° C. in an embodiment. The applied conductive paste can go directly to the next firing step without the drying step in another embodiment.

The conductive paste 70 for forming an n-type electrode is also applied onto the second passivation layers 40b on the n⁺-layer 30 by a patterning method such as screen printing, stencil printing or dispensing in an embodiment. The applied conductive paste 70 is then dried for 10 seconds to 10 minutes at 50-200° C. in an embodiment. The applied conductive paste can go directly to the next firing step without the drying step in another embodiment. In one embodiment, the conductive paste 70 on the second passivation layer 40b can be different in composition from the conductive paste 60 on the first passivation layer 40a. The composition of the conductive paste 70 can be adjusted depending on, for example, the doping profile of n⁺ layer, material or thickness of the second passivation layer 40b.

In another embodiment, the conductive paste 60 applied on the p-type emitter 20 and the conductive paste 70 applied on the n⁺-layer 30 are the same in composition. In one embodiment, both conductive paste 60 and 70 are applied at the same time or continuously prior to drying.

Firing of the conductive pastes is then carried out. The conductive pastes 60 and 70 fire through the passivation layers 40a and 40b during the firing process in a way that a p-type electrode 61 and an n-type electrode 71 have good electrical connection with the p-type emitter 20 and the n⁺-layer 30 respectively (FIG. 1(f)). When the connections between these electrodes and semiconductor are improved, the electrical properties of a solar cell will also be improved.

An infrared furnace can be used for the firing process. Firing conditions can be controlled in consideration of firing temperature and firing time. The total firing time may be from 20 seconds to 15 minutes in an embodiment. The measured peak temperature on the surface of the substrate is 450 to 1000° C. in one embodiment, 650 to 870° C. in another embodiment, and 700 to 800° C. in another embodiment, In another embodiment, the measured temperature on the surface of the substrate can be 10 to 60 seconds at over 400° C. and 2 to 10 seconds at over 600° C. The firing temperature can be measured with a K-type thermocouple attached to the upper surface of the substrate where the aforementioned conductive paste is going to be applied. With the firing temperature and time inside the specified range, less damage occurs to the semiconductor substrate during firing.

The p-type solar cell electrode formed on the p-type emitter can be formed efficiently with a high aspect ratio, a narrow line width (fine line) and low line resistance (ohms/cm). The line width of the electrode is 10 to 100 μm In one embodiment, 20 to 60 μm in another embodiment.

The height of the electrode is 4 to 60 μm in one embodiment, 10 to 35 pm in another embodiment. An aspect ratio (height/width) is 0.4 to 0.6 in one embodiment, 0.37 to 0.55 in another embodiment. In this specification, “aspect ratio” means the value of height/width of the formed electrode, and specific measurement and calculation methods are shown in the Examples given below.

The line resistance (ohms/cm) of the electrode is no more than 0.5 (ohms/cm) in one embodiment, no more than 0.4 (ohms/cm) in another embodiment, A solar cell electrode with such aspect ratio and low line resistance (ohms/cm) can show excellent photoelectric conversion efficiency (%).

### Conductive Paste

The conductive paste to form an electrode comprises a conductive powder, an aluminum powder, a glass frit and an organic medium.

(i) Silver Powder

The conductive powder enables the paste to transport electrical current. In an embodiment, silver powder, which has relatively high electrical conductivity, is used so that resistive power loss of a solar cell can be minimized. Ag powder sinters and does not form oxides after firing in air and provides highly conductive bulk material. The silver powder is 90% or more in purity in an embodiment, 95% or more in purity in another embodiment and 99% or more in purity in another embodiment.

The silver powder is 70 to 99.75 weight percent (wt %) in an embodiment, 75 to 98 wt % in another embodiment, and 80 to 96 wt % in another embodiment, based on the total weight of the conductive paste. A silver powder with such amount in the conductive paste can retain sufficient conductivity for solar cell applications.

In one embodiment, the silver powder can be flaky or spherical in its shape.

The particle diameter of the silver powder is 0.1 to 10 μm in an embodiment, 0.5 to 7 μm in another embodiment, and 1 to 4 μm in another embodiment. The silver powder with such particle diameter can be adequately dispersed in the organic binder and solvent, and smoothly applied onto the substrate. In an embodiment, the silver powder can be a mixture of two or more types of silver powders with different particle diameters or different particle shapes. In an embodiment, the silver powder can be mixed with other metal powders.

The particle diameter is obtained by measuring the distribution of the particle diameters by using a laser diffraction scattering method and can be specified by D50, which refers to the median particle size by volume in the distribution. The particle size distribution can be measured with a commercially available device, such as the Microtrac model X-100.

(ii) Aluminum Powder

Aluminum (Al) powder is a metal powder containing at least Al. The purity of the Al powder is 98% or higher in an embodiment, and 99% or higher in another embodiment. The content of the Al powder is 0.1 to 3.0 wt % in an embodiment, 1.0 to 2.5 wt % in another embodiment, and 1.5 to 2.3 wt % in another embodiment, based on the total weight of the conductive paste. Including Al powder in such amount in the conductive paste can reduce the contact resistance and improve the electrical properties of a solar cell.

The particle diameter (D50) of the Al powder is not larger than 3 μm in an embodiment. The particle diameter (D50) of the Al powder is not larger than 2.8 μm in an embodiment. The lower limit of the particle diameter is 0.5 μm in an embodiment, 1.0 μm in another embodiment, and 1.5μm in another embodiment. With such small particle diameter of Al powder, electrical properties of a solar cell can be improved. To measure the particle diameter (D50) of the Al powder, the same method as used for the conductive powder can be applied.

In one embodiment, the Al powder can be flaky, nodular, or spherical in its shape. The nodular powder is irregular particles with knotted, rounded shapes. In another embodiment, Al powder can be spherical.

(iii) Glass Frit

Glass frits help to form an electrical contact through the passivation layer during the consequent firing process and facilitate binding of the electrode to the semiconductor substrate. The glass frits may also promote sintering of the conductive powder.

The content of the glass frit is 5 wt % to 10wt %, based on the total weight of the conductive paste. The content is 5wt % to 8wt % in another embodiment, and 5wt % to 7wt % in another embodiment, based on the total weight of the conductive paste in another embodiment. By adding glass frit with such high amount, electrical properties of a solar cell can be improved.

The glass frit composition is not limited to any specific composition. A lead-free glass or a lead containing glass can be used, for example.

In one embodiment, the glass frit comprises a lead containing glass frit containing lead oxide and one or more of oxides selected from the group consisting of silicon oxide (SiO₂), boron oxide (B₂O₃) and aluminum oxide (Al₂O₃).

Lead oxide (PbO) is 40 to 80 mol % in an embodiment, and 42 to 73 mol % in another embodiment, and 45 to 68 mol % in another embodiment based on the total molar fraction of each component in the glass frit.

Silicon oxide (SiO₂) is 0.5 to 40 mol % in an embodiment, 1 to 33 mol % in another embodiment, and 1.3 to 28 mol % in another embodiment, based on the total molar fraction of each component in the glass frit.

Boron oxide (B₂O₃) is 15 to 48 mol % in an embodiment, 20 to 43 mol % in another embodiment, and 22 to 40 mol % in another embodiment, based on the total molar fraction of each component in the glass frit.

Aluminum oxide (Al₂O₃) is 0.01 to 6 mol % in an embodiment, 0.09 to 4.8 mol % in another embodiment, and 0.5 to 3 mol % in another embodiment, based on the total molar fraction of each component in the glass frit.

In another embodiment, the glass frit comprises a lead-free glass frit not containing lead oxide (PbO) and containing one or more of oxides selected from the group consisting of boron oxide (B₂O₃), zinc oxide (ZnO), bismuth oxide (Bi₂O₃), silicon oxide (SiO₂), aluminum oxide (Al₂O₃), alkaline-earth metal oxide, and alkali metal oxide.

Boron oxide (B₂O₃) is 20 to 48 mol % in an embodiment, 25 to 42 mol % in another embodiment, and 28 to 39 mol % in another embodiment, based on the total molar fraction of each component in the glass frit,

Zinc oxide (ZnO) is 15 to 45 mol % in an embodiment, 25 to 38 mol % in another embodiment, and 28 to 36 mol % in another embodiment, based on the total molar fraction of each component in the glass frit.

Bismuth oxide (Bi₂O₃) is 15 to 40 mol % in an embodiment, 18 to 35 mol % in another embodiment, and 19 to 30 mol % in another embodiment based on the total molar fraction of each component in the glass frit.

Silicon oxide (SiO₂) is 0.5 to 20 mol % in an embodiment, 0.9 to 6 mol % in another embodiment, and 1 to 3 mol % in another embodiment, based on the total molar fraction of each component in the glass frit.

Aluminum oxide (Al₂O₃) is 0.9 to 8 mol % in an embodiment, 2.5 to 7.5 mol % in another embodiment, 3 to 7.3 mol % in still further embodiment, based on the total molar fraction of each component in the glass frit.

“Alkaline-earth metal oxide” is a general term for the group consisting of beryllium oxide (BeO), magnesium oxide (MgO), calcium oxide (CaO), strontium oxide (SrO) and barium oxide (BaO). The alkaline-earth metal oxide is BaO, CaO, MgO or a mixture thereof in an embodiment, and BaO, CaO or a mixture thereof in another embodiment. The alkaline-earth metal oxide is 0.5 to 20 mol % in an embodiment, 0.9 to 8 mol % in another embodiment, 1 to 7.5 mol % in still another embodiment, based on the total molar fraction of each component in the glass frit.

“Alkali metal oxide” is a general term for the group consisting of lithium oxide (Li₂O), sodium oxide (Na₂O), potassium oxide (K₂O), rubidium (Rb₂O) and cesium oxide (Cs₂O) The alkali metal oxide can be Li₂O in an embodiment. The alkaline metal oxide is 0.5 to 20 mol % in an embodiment, 0.9 to 8 mol % in another embodiment, and 1 to 7.5 mol % in still another embodiment, based on the total molar fraction of each component in the glass frit,

The softening point of the glass frits is less than 400° C. in an embodiment, 300 to 400° C. in another embodiment, and 350 to 390° C. in another embodiment. In this specification, “softening point” is determined by differential thermal analysis (DTA). To determine the glass softening point by DTA, sample glass is ground and is introduced with a reference material into a furnace to be heated at a constant rate of 5 to 20° C. per minute. The difference in temperature between the two is detected to investigate the evolution and absorption of heat from the material. The glass softening point (Ts) can be determined by the temperature at the third inflection point in the DTA curve.

Glass frit can be prepared by methods well known in the art. For example, the glass component can be prepared by mixing and melting raw materials such as oxides, hydroxides, carbonates, making into a cullet by quenching, followed by mechanical pulverization (wet or dry milling). Thereafter, if needed, classification is carried out to the desired particle size,

### (iv) Organic Medium

The conductive paste comprisesan organic medium, which comprises organic binder and solvent.

In one embodiment, the organic binder can comprise ethyl cellulose, ethylhydroxyethyl cellulose, Foralyn™ (pentaerythritol ester of hydrogenated rosin), dammar gum, wood rosin, phenolic resin, acryl resin, polymethacrylate of lower alcohol or a mixture thereof.

In one embodiment, the solvent can comprise terpenes such as alpha- or beta-terpineol or mixtures thereof, Texanol™. (2,2,4-trimethy-1,3-pentanediolmonoisobutyrate), kerosene, dibutylphthalate, butyl Carbitol™, butyl Carbitol™ acetate, hexylene glycol, monobutyl ether of ethylene glycol monoacetate, diethylene glycol monobutyl ether, diethylene glycol monobutyl ether acetate, diethylene glycol dibutyl esther, bis(2-(2-butoxyethoxy)ethyl)adipate, dibasic esters such as DBE®, DBE®-2, DBE®-3, DBE®-4, DBE®-5, DBE®-6, DBE®-9, and DBE®-1B from lnvista, octyl epoxy tallate, isotetradecanol, and petroleum naphtha, or a mixture thereof.

The amount of organic medium is 3 to 30 wt % in one embodiment, 5 to 25 wt % in another embodiment, 7 to 23 wt % in further embodiment, based on the total weight of the conductive paste.

The organic medium can be burned off during the firing step so that p-type electrode ideally contains no organic residue. However, actually, a certain amount of residue can remain in the resulting p-type electrode as long as it does not degrade the electrical properties of the p-type electrode.

(v) Additives

Additives such as a thickener, a stabilizer, a dispersant, a viscosity modifier and a surfactant can be added to a conductive paste as the need arises. The amount of the additives depends on the desired characteristics of the resulting conductive paste and can be chosen by people in the industry. Multiple kinds of the additives can be added to the conductive paste.

Although components of the conductive paste were described above, the conductive paste can contain impurities coming from raw materials or contaminated during the manufacturing process. However, the presence of the impurities would be allowed (defined as benign) as long as it does not significantly alter anticipated properties of the conductive paste. For example, the p-type electrode manufactured with the conductive paste can achieve sufficient electric properties described herein, even if the conductive paste includes benign impurities.

The viscosity of the conductive paste is 200 to 1000 Pa·s in one embodiment, 300 to 800 Pas in another embodiment, 350 to 700 Pa·s in further embodiment. With having such viscosity, the conductive paste has a proper value of viscosity and hence has excellent printability. In the present invention, the viscosity of the conductive paste is a value obtained by measurement at 25° C., 10 rpm using a Brookfield HBT viscometer with a #14 spindle and a SC4-14!6R utility cup.

The inorganic solids content of the conductive paste is calculated as the percentage (wt %) of inorganic solids relative to the total weight of the conductive paste. The inorganic solids typically consist of conductive powders and glass frit. In one embodiment, the inorganic solids content is 68.5 to 96.7 wt % and 85 to 94 wt % in another embodiment.

### EXAMPLES

The present invention is illustrated by, but is not limited to, the following examples.

### (Conductive Paste Preparation)

Conductive pastes were prepared according to the following procedure by using the following materials.

Conductive powder: Spherical silver (Ag) powder with particle diameter (D50) of 2 μm as measured with a laser diffraction scattering method.

Aluminum (Al) powder #1: Spherical aluminum (Al) powder with diameter (D50) of 1.9 μm as measured with a laser diffraction scattering method.

Aluminum (Al) powder #2: Spherical aluminum (Al) powder with diameter (D50) of 2.7 μm as measured with a laser diffraction scattering method.

Aluminum (Al) powder #3: Spherical aluminum (Al) powder with diameter (D50) of 3.6 μm as measured with a laser diffraction scattering method.

Glass frit: PbO—SiO₂—Al₂O₃—B₂O₃-type frit. The softening point determined by DTA was 325° C.

Organic medium: mixture of Butyl Carbitol™ Acetate, Propylene Carbonate, Texanol™, Ethyl Cellulose and additives.

The organic medium was mixed with the viscosity modifier for 15 minutes. To enable the uniform dispersion of a small amount of Al powder in the conductive paste, the Ag powder and the Al powder were dispersed in the organic medium separately to mix together afterward. First, the Al powder was dispersed in some of the organic medium and mixed for 15 minutes to prepare an Al slurry. Second, the glass frit was dispersed in the rest of the organic medium and mixed for 15 minutes and then the Ag powder was incrementally added to prepare Ag paste. The mixture was repeatedly passed through a 3-roll mill at progressively increasing pressures from 0 to 400 psi. The gap of the rolls was adjusted to 1 mil.

The Ag paste and the Al slurry were mixed together to prepare the conductive paste. Finally, additional organic medium or thinners were mixed to adjust the viscosity of the paste. The content of each component is shown in Table 1. The viscosity measured at 10 rpm and 25° C. with a Brookfield HBT viscometer and #14 spindle and a SC4-14/6R utility cup was 275 Pa·s.

### (Manufacture of Test Pieces)

The conductive paste obtained above was screen printed onto a SiNₓ layer (passivation layer) with 90 nm average thickness, formed on a p-type emitter of an n-base type mono-silicon substrate (250 cm², 6inch×6 inch pseudo-square).

The printed conductive paste was dried at 200° C. for 3 min in a convection oven.

Electrodes were then obtained by firing the printed conductive pastes in an IR heating type of belt furnace (CF-7210B, Despatch industry) at peak temperature setting with 885° C. The furnace set temperature of 885° C. corresponded to a measured temperature at the upper surface of the silicon substrate of 761° C. Firing time from furnace entrance to exit was 80 seconds. The firing profile had a ramping rate from 400 to 600° C. in 11 seconds, and the period over 600° C. for 6 seconds. The temperature was measured at the upper surface of the silicon substrate with a K-type thermocouple and recorded using an environmental data logger (Datapaq® Furnace Tracker® System, Model DP9064A, Datapaq Ltd.). The belt speed of the furnace was 600 cpm.

### (Test Procedure)

### Cell I-V Characteristics

The N-type solar cells produced according to the method described herein will be tested for efficiency with a commercial IV tester (FRIWO®, BERGER Corporation). The Xe Arc lamp in the IV tester simulates the sunlight with a known intensity and spectrum with air mass value of 1.5 to irradiate the p-type emitter side of the n-base solar cell. The tester will be “four-point probe method” to measure current (I) and voltage (V) at approximately 400 load resistance settings to determine the cell's I-V curve. The bus bars which will be printed on the p-type emitters, front sides of the cells, will be connected to the multiple probes of the IV tester and the electrical signals will be transmitted through the probes to the data processing computer to obtain solar cell's I-V characteristics, including the short circuit current, the open circuit voltage, the fill-factor (FF), series resistance, and the cell efficiency.

As Table 1 shows, it was found that the cell performance of the present invention was higher. Comparison of Example 1, Example 2 and Control 1 indicates that finer Al powder contributes to high efficiency of N-type solar cell. As mentioned at the beginning of the specification, even 0.1% improvement is sought for in the solar industry. Comparison of Example 1 and Control 1 with Control 2 and Control 3 indicate excessive amount of Al powder is not preferable. The same trend was confirmed for Control 5 and Control 8. Comparison of Example 1, Example 2, Control 1 and Control 2 with Control 4, Control 5, Control 6 and Control 7 indicates high frit content is preferable.

TABLE 1

| | Example | Example | Control | Control | Control | Control | Control | Control | Control | Control |
|---|---|---|---|---|---|---|---|---|---|---|
| | 1 | 2 | 1 | 2 | 3 | 4 | 5 | 6 | 7 | 8 |
| Frit (%) | 5.8 | 5.8 | 5.8 | 5.8 | 5.61 | 2.9 | 2.9 | 2.9 | 2.9 | 2.9 |
| Al powder D₅₀ = | 2.15 | 0 | 0 | 4.3 | 0 | 2.15 | 0 | 0 | 4.3 | 0 |
| 1.9 um | | | | | | | | | | |
| Al powder D₅₀ = | 0 | 2.15 | 0 | 0 | 0 | 0 | 2.15 | 0 | 0 | 4.3 |
| 2.7 um | | | | | | | | | | |
| Al powder D₅₀ = | 0 | 0 | 2.15 | 0 | 4.3 | 0 | 0 | 2.15 | 0 | 0 |
| 3.6 um | | | | | | | | | | |
| Voc (mV) | 666.3 | 661.6 | 661.5 | 640 | 636.2 | 659 | 655.2 | 650.8 | 633.1 | 630.8 |
| FF (%) | 77.94 | 78.41 | 78.14 | 77.32 | 76.3 | 76.28 | 77.49 | 77.44 | 75.82 | 76.68 |
| Rhoc (mohm.cm²) | 1.93 | 0.93 | 1.6 | 0.79 | 1.56 | 8.32 | 3.23 | 3.08 | 0.71 | 0.81 |
| Ncell Efficiency (%) | 21.72 | 21.71 | 21.61 | 20.49 | 20.18 | 21.02 | 21.23 | 21.07 | 19.99 | 20.12 |

We claim:

1. A conductive paste for N-type solar cells, comprising:
(a) 70 to 99.75 wt % of a silver power;
(b) 0.1 to 3.0 wt % of an aluminum powder, wherein D50 of the aluminum powder is not larger than 3 μm;
(c) 5 to 10 wt % of a glass frit; and
(d) 3 to 30 wt % of an organic medium;
wherein wt % is based on the total weight of the paste composition.

2. A conductive paste of claim 1, wherein content of the aluminum powder is 1.0 to 2.5 wt %.

3. A conductive paste of claim 1, wherein D50 of the aluminum powder is larger than 1.0 μm and smaller than 2.8 μm.

4. A conductive paste of claim 1, wherein content of the glass frit is 5-8 wt %.

5. A conductive paste of claim 1, wherein softening point of the glass frit is less than 400° C.

6. A conductive paste of claim 1, wherein the conductive paste is for use in forming an electrode in an N-type solar cell comprising an n-doped semiconductor substrate having at least one insulating layer on a main surface thereof, and wherein the conductive paste, when fired, is capable of penetrating the at least one insulating layer.

7. A method for manufacturing N-type solar cells, comprising the steps of:
preparing an N-type solar cell substrate, wherein the N-type solar cell substrate comprises an n-doped semiconductor substrate, a p-type emitter formed on one side of the semiconductor substrate, and a passivation layer formed on the p-type emitter;
applying a conductive paste on the semiconductor substrate, wherein the conductive paste comprises (a) 70 to 99.75 wt % of a silver power; (b) 0.1 to 3.0 wt % of an aluminum powder, wherein D50 of the aluminum powder is not larger 3 μm; (c) 5 to 10 wt % of a glass frit; and (d) 3 to 30 wt % of an organic vehicle; wherein wt % is based on the total weight of the paste composition; and
firing the applied conductive paste to form a solar cell electrode in electric contact with the p-type emitter.

8. An N-type solar cell comprising electrode formed from the conductive paste of claim 1.
